(19) United States
(12) Patent Application Publication
(10) Pub. No.: US 2004/0256648 A1
(43) Pub. Date: Dec. 23, 2004

(54) Ferroelectric layer, method of manufacturing ferroelectric layer, ferroelectric capacitor, and ferroelectric memory

(75) Inventors: Junichi Karasawa, Shimosuwa-machi (JP); Koji Ohashi, Chino-shi (JP); Yasuaki Hamada, Suwa-shi (JP); Takeshi Kijima, Matsumoto-shi (JP); Eiji Natori, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/807,288

(22) Filed: Mar. 24, 2004

(30) Foreign Application Priority Data
Mar. 27, 2003 (JP) 2003-088219

(51) Int. Cl. H01L 29/76

(52) U.S. Cl. 257/295

(57) ABSTRACT

A ferroelectric layer including space charges. The space charges show a concentration peak at least at one of an upper portion and a lower portion of the ferroelectric layer in a direction of the thickness of the ferroelectric layer.

Japanese Patent Application No. 2003-88219, filed on Mar. 27, 2003, is hereby incorporated by reference in its entirety.

### BACKGROUND OF THE INVENTION

The present invention relates to a ferroelectric layer, a method of manufacturing the ferroelectric layer, a ferroelectric capacitor, and a ferroelectric memory. More particularly, the present invention relates to a ferroelectric layer suitable for nondestructive readout.

A ferroelectric memory is proposed as an IC memory. The ferroelectric memory is formed by sandwiching a ferroelectric layer between a pair of electrodes. The ferroelectric film has hysteresis characteristics as indicated by a solid line in FIG. 1, and retains data by spontaneous polarization. An example of an operation method for the ferroelectric memory is described below.

A positive remanent polarization (“A” in FIG. 1) is defined as “1”, and a negative remanent polarization (“B” in FIG. 1) is defined as “0”, for example. In the case where data “0” has been written in a memory cell, the polarization state is reversed from the negative polarization state to the positive polarization state when a positive read voltage is applied. In the case where data “1” has been written in a memory cell, the polarization state is not reversed. “0” or “1” is judged by detecting the amount of charge corresponding to each polarization state. In the above-described operation method, it is necessary to apply a rewrite voltage in order to cause the ferroelectric film of which the polarization state has been reversed by the application of the read voltage to be returned to the original polarization state.

In recent years, nondestructive readout as follows has been proposed as another operation method for the ferroelectric memory. In this nondestructive readout, data is read by utilizing the difference in inclination between A and B of the hysteresis characteristics indicated by the solid line in FIG. 1, specifically, the difference in capacitance between A and B, when applying a small voltage (see Integrated Ferroelectrics, 2001, Vol. 40, pp. 41-45). According to this method, it is unnecessary to apply the rewrite voltage for causing the ferroelectric film, of which the polarization state has been changed from one polarization state to the other polarization state by the application of voltage during reading, to be returned to the original polarization state. However, the difference in inclination between A and B of the hysteresis characteristics is generally small. Therefore, in order to increase the read margin of the ferroelectric memory by using this method, the difference in inclination between A and B of the hysteresis characteristics, specifically, the difference in capacitance between A and B, must be increased as much as possible.

### BRIEF SUMMARY OF THE INVENTION

The present invention may provide a ferroelectric layer which is suitable for the nondestructive readout and in which the difference in inclination between A and B of the hysteresis characteristics shown in FIG. 1 is large, and a method of manufacturing the ferroelectric layer. Moreover, the present invention may provide a ferroelectric capacitor and a ferroelectric memory using such a ferroelectric layer.

According to a first aspect of the present invention, there is provided a ferroelectric layer including space charges,

wherein the space charges show a concentration peak at least at one of an upper portion and a lower portion of the ferroelectric layer in a direction of the thickness of the ferroelectric layer.

According to a second aspect of the present invention, there is provided a method of manufacturing a ferroelectric layer including space charges,

wherein the space charges are formed by causing a crystal defect to occur at least at one of an upper portion and a lower portion of the ferroelectric layer in a direction of the thickness of the ferroelectric layer.

According to a third aspect of the present invention, there is provided a method of manufacturing a ferroelectric layer, comprising:

forming a first ferroelectric section including space charges generated by causing a crystal defect to occur; and

forming a second ferroelectric section over the first ferroelectric section.

According to a fourth aspect of the present invention, there is provided a ferroelectric capacitor comprising the above ferroelectric layer.

According to a fifth aspect of the present invention, there is provided a ferroelectric memory comprising the above ferroelectric capacitor.

### BRIEF DESCRIPTION OF THE SEVERAL VIEWS OF THE DRAWING

FIG. 1 is a graph showing hysteresis characteristics of a ferroelectric layer.

FIG. 2A is a cross-sectional view schematically showing a ferroelectric capacitor according to one embodiment of the present invention; and FIG. 2B is a graph showing distribution of space charges in the ferroelectric layer.

FIG. 3A is a cross-sectional view schematically showing a ferroelectric capacitor according to a modification of the embodiment of the present invention; and FIG. 3B is a graph showing distribution of space charges in the ferroelectric layer of the modification.

### DETAILED DESCRIPTION OF THE EMBODIMENTS

The embodiments of the present invention will be described below in detail.

(1) According to one embodiment of the present invention, there is provided a ferroelectric layer including space charges,

wherein the space charges show a concentration peak at least at one of an upper portion and a lower portion of the ferroelectric layer in a direction of the thickness of the ferroelectric layer.

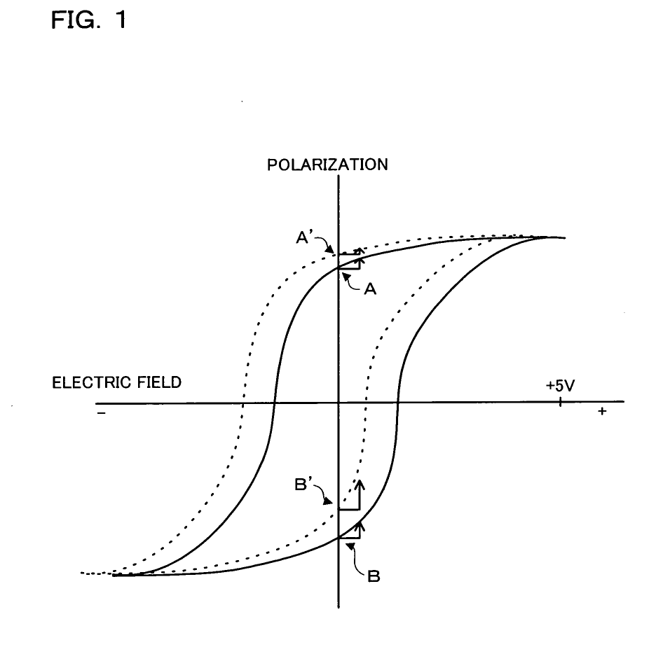

Therefore, an internal bias field can be generated in the ferroelectric layer in the direction from the upper or lower portion having a space charge concentration peak to the other portion. As a result, a ferroelectric layer having hysteresis characteristics shifted in the positive or negative direction along the voltage axis as shown by a dashed line in FIG. 1 can be provided.

In this ferroelectric layer, the space charges may show a concentration peak at the upper portion and the lower portion of the ferroelectric layer; and

the polarities of the space charges at the upper and lower portions may be different from each other.

Therefore, a ferroelectric layer in which occurs an internal bias field having a greater intensity can be obtained. As a result, a ferroelectric layer having hysteresis characteristics shifted in the positive or negative direction along the voltage axis larger than the case in which the space charges show a concentration peak at least at one of the upper and lower portions, as shown by a dashed line in FIG. 1, can be provided.

(2) According to one embodiment of the present invention, there is provided a method of manufacturing a ferroelectric layer including space charges, wherein the space charges are formed by causing a crystal defect to occur at least at one of an upper portion and a lower portion of the ferroelectric layer in a direction of the thickness of the ferroelectric layer.

This makes it possible to manufacture a ferroelectric layer having a space charge concentration peak at the upper or lower portion of the ferroelectric layer by generating a crystal defect to at the upper or lower portion in the direction of the thickness of the ferroelectric layer.

In this method of manufacturing a ferroelectric layer,

the space charges may be formed by causing a crystal defect to occur at the upper portion and the lower portion of the ferroelectric layer; and

the polarities of the space charges at the upper and lower portions may be different from each other.

This makes it possible to manufacture a ferroelectric layer having space charge concentration peaks at the upper and lower portions of the ferroelectric layer by intentionally generating a crystal defect at the upper and lower portions of the ferroelectric layer with respect to the thickness of the ferroelectric layer.

(3) According to one embodiment of the present invention, there is provided a method of manufacturing a ferroelectric layer, comprising:

forming a first ferroelectric section including space charges generated by causing a crystal defect to occur; and

forming a second ferroelectric section over the first ferroelectric section.

This makes it possible to manufacture a ferroelectric layer having a space charge concentration peak at the upper or lower portion of the ferroelectric layer in the direction of the film thickness by stacking the first ferroelectric section including space charges and the second ferroelectric section having a usual composition.

This method of manufacturing a ferroelectric layer may further comprise:

forming a third ferroelectric section including space charges generated by causing a crystal defect to occur over the second ferroelectric section,

wherein the polarities of the space charges in the first ferroelectric section and the third ferroelectric section may be different from each other.

According to this feature, the ferroelectric layer is formed by stacking the first to third ferroelectric sections, and space charges of different polarities are included in the first and third ferroelectric sections. Therefore, a ferroelectric layer having space charge concentration peaks at the upper and lower portions of the ferroelectric layer in the direction of the film thickness can be provided.

The above method of manufacturing a ferroelectric layer may further include the following features.

In this method of manufacturing a ferroelectric layer,

the crystal defect may be caused by the absence of part of substances in the stoichiometric composition of the ferroelectric layer.

This makes it possible to intentionally generate a crystal defect by using a liquid material in which the percentage of a predetermined component of a ferroelectric layer is decreased to form a ferroelectric layer. As a result, a ferroelectric layer having a space charge concentration peak at least at one of the upper and lower portions of the ferroelectric layer can be manufactured.

In this method of manufacturing a ferroelectric layer, the crystal defect may be caused by crystallization heat treatment in which oxygen partial pressure is controlled.

This makes it possible to intentionally generate an oxygen defect in a ferroelectric layer by performing crystallization in which oxygen partial pressure is controlled after forming a coating film by using a liquid material including a ferroelectric material. As a result, a ferroelectric layer having a space charge concentration peak at least at one of the upper and lower portions of the ferroelectric layer can be manufactured.

In this method of manufacturing a ferroelectric layer, the crystal defect may be caused by introducing impurities.

This makes it possible to generate space charges at a desired position, whereby a ferroelectric layer having a space charge concentration peak at least at one of the upper and lower portions of the ferroelectric layer can be manufactured.

According to one embodiment of the present invention, there is provided a ferroelectric capacitor comprising the above ferroelectric layer.

According to one embodiment of the present invention, there is provided a ferroelectric memory comprising the above ferroelectric capacitor.

The ferroelectric memory according to the embodiments of the present invention includes a ferroelectric capacitor having a ferroelectric layer in which space charges are intentionally distributed in the direction of the film thickness. The hysteresis characteristics of such a ferroelectric layer are shifted in the positive or negative direction along the voltage axis as indicated by the dashed line in FIG. 1, whereby the difference in inclination between A′ and B′ shown in FIG. 1 is increased when applying a small voltage. Therefore, in the ferroelectric memory according to the embodiments of the present invention, “0” or “1” can be easily determined, whereby a highly reliable ferroelectric memory can be provided. Moreover, since the polarization of the ferroelectric layer is not reversed by the voltage applied during readout, it is unnecessary to apply a voltage for recovering the polarization state, whereby deterioration of the ferroelectric layer can be reduced.

The ferroelectric layer, the method of manufacturing the ferroelectric layer, the ferroelectric capacitor, and the ferroelectric memory according to the embodiments of the present invention are described below in more detail with reference to the drawings.

1. Ferroelectric Capacitor

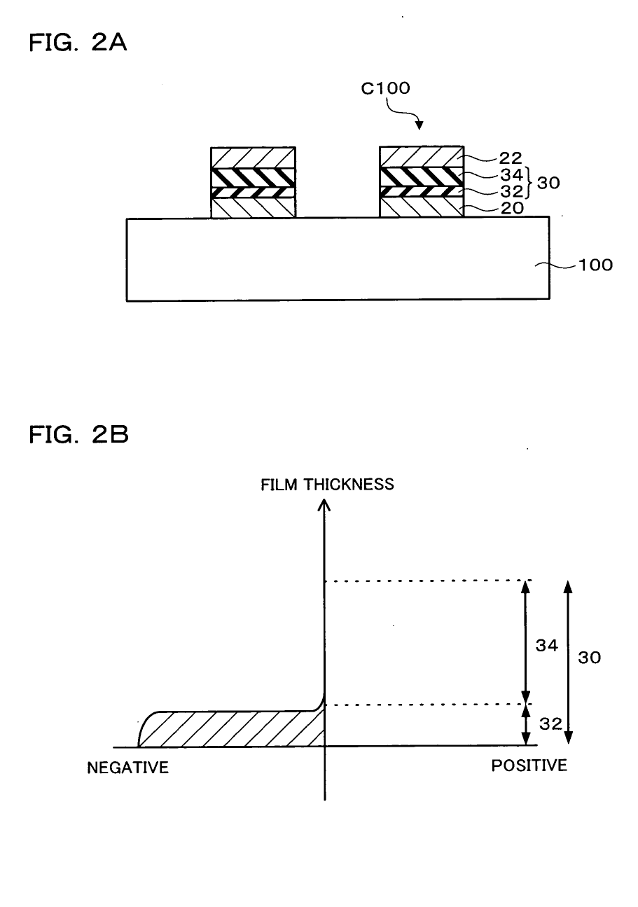

A ferroelectric capacitor C100 including a ferroelectric layer according to one embodiment of the present invention is described with reference to FIGS. 2A and 2B. FIG. 2A is a view schematically showing a cross section of the ferroelectric capacitor C100 of this embodiment. FIG. 2B is a view showing a distribution of space charges with respect to the thickness of the ferroelectric layer.

As shown in FIG. 2A, the ferroelectric capacitor C100 in this embodiment is formed on a substrate 10. The substrate 10 includes a transistor formation region and the like. The ferroelectric capacitor C100 is formed by stacking a first electrode (lower electrode) 20, a ferroelectric layer 30, and a second electrode (upper electrode) 22 in that order. As shown in FIG. 2B, the ferroelectric layer 30 has a negative space charge concentration peak in a lower layer with respect to the film thickness, that is, in a layer on the side of the first electrode 20. The ferroelectric layer 30 having a negative space charge concentration peak at the lower portion of the ferroelectric layer 30 is described in this embodiment, but a space charge concentration peak may be formed at an upper portion of the ferroelectric layer 30, and the polarity of space charges may be positive.

As an example of a specific feature of the ferroelectric layer 30, the following feature may be employed. The ferroelectric layer 30 is formed by stacking a first ferroelectric section 32 and a second ferroelectric section 34, for example. The first ferroelectric section 32 is formed by using a film in which the number of negative space charges is greater than that of the second ferroelectric section 34. According to this feature, the ferroelectric layer 30 has a space charge concentration peak as shown in FIG. 2B. As a result, an internal bias field can be caused to occur in the ferroelectric layer 30 in the direction from the upper portion to the lower portion with respect to the film thickness.

According to the ferroelectric capacitor C100 in this embodiment, the ferroelectric layer 30 has a space charge concentration peak at the lower portion (on the side of the first electrode 20) in the direction of the film thickness. Therefore, an internal bias field can be caused to occur in the direction from the upper portion to the lower portion of the ferroelectric layer 30. As a result, hysteresis characteristics of the ferroelectric layer 30 can be shifted along the voltage axis.

The ferroelectric layer 30 in this embodiment is formed by stacking two layers of ferroelectric sections having different space charge concentrations. However, the present invention is not limited thereto. It suffices that the ferroelectric layer 30 have a space charge concentration peak at the upper or lower portion of the ferroelectric layer 30. For example, two or more layers of ferroelectric sections having different space charge concentrations may be stacked.

Modification

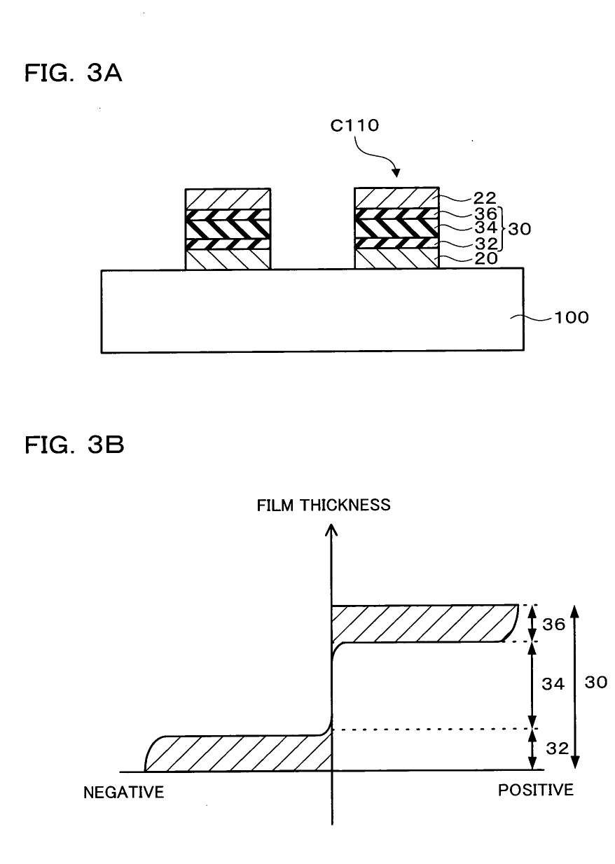

The above-described embodiment illustrates the ferroelectric layer 30 having a space charge concentration peak only at the lower portion in the direction of the film thickness. This modification illustrates a ferroelectric capacitor C 110 including the ferroelectric layer 30 having space charge concentration peaks of different polarities at the upper and lower portions in the direction of the film thickness with reference to FIGS. 3A and 3B. FIG. 3A is a view schematically showing a cross section of the ferroelectric capacitor C110 according to this modification. FIG. 3B is a view showing a space charge distribution with respect to the film thickness of the ferroelectric layer 30. A positive space charge concentration peak is present at the upper portion of the ferroelectric layer 30 and a negative space charge concentration peak is present at the lower portion of the ferroelectric layer 30 in this modification. However, the present invention is not limited thereto.

As shown in FIG. 3A, the ferroelectric capacitor C110 according to the modification is formed by stacking the first electrode 20, the ferroelectric layer 30, and the second electrode 22. As shown in FIG. 3B, in the ferroelectric layer 30, films having space charge concentration peaks of different polarities are formed at the upper and lower portions with respect to the film thickness, specifically, in the layers on the side of the first electrode 20 and the side of the second electrode 22. As an example of a specific feature of such a ferroelectric layer 30, the following feature may be employed. As shown in FIG. 3A, the ferroelectric layer 30 is formed by stacking first to third ferroelectric sections 32, 34, and 36, for example. The first ferroelectric section 32 and the third ferroelectric section 36 include a large number of space charges in comparison with the second ferroelectric section 34. The first ferroelectric section 32 and the third ferroelectric section 36 include space charges of different polarities. According to this feature, the ferroelectric layer 30 has space charge concentration peaks as shown in FIG. 3B.

2. Method of Manufacturing Ferroelectric Capacitor

A method of manufacturing the ferroelectric capacitor C100 shown in FIG. 2A is described below. The following embodiment illustrates the case where a PZT layer is formed as the ferroelectric layer 30.

(1) The first electrode 20 is formed on the substrate 10. There are no specific limitations to the formation method for the first electrode 20. For example, a vapor phase method, a liquid phase method, or the like may be used. As the vapor phase method, sputtering, vacuum deposition, MOCVD, or the like may be used. As the liquid phase method, electroplating, electroless plating, or the like may be used. There are no specific limitations to the material for the first electrode 20. For example, Ir, IrOₓ, Pt, Ru, RuOₓ, SrRuOₓ, or LaSrCoOₓ, may be used.

(2) The ferroelectric layer 30 is formed. A coating film is formed from a first liquid material on the first electrode 20 by using a solution deposition method. As the first liquid material, a solution having a composition which easily causes a crystal defect to occur is used. Specifically, the first ferroelectric section 32 including a large number of space charges is formed by causing a crystal defect to occur. In this embodiment, a liquid material which is adjusted so that the percentage of Pb included in PZT coincides with the stoichiometric composition is used. In the case of forming a PZT layer having no crystal defect, a liquid material including Pb in excess of the stoichiometric composition is used, since Pb becomes deficient in a heating step for crystallization performed later. In this embodiment, since the liquid material including Pb at the stoichiometric composition is used, Pb becomes deficient in the heating step for crystallization performed later, whereby a crystal defect can be caused to occur. The coating film prepared in this manner is subjected to presintering and heating for crystallization to form the first ferroelectric section 32. In this case, the chemical formula of PZT is expressed by (Pb²⁺□)(Zr⁴⁺Ti⁴⁺)O₃²⁻ (□ represents vacancy), and the lead defect has an effective charge of −1.

(3) The second ferroelectric section 34 is formed on the first ferroelectric section 32. In more detail, a coating film is formed from a second liquid material on the first ferroelectric section 32 by using a solution deposition method. In this embodiment, a liquid material in which Pb is added to a liquid material adjusted to the stoichiometric composition of PZT (Zr/Ti=35/65) so that the amount of Pb is in 10% excess of the stoichiometric composition at a molar ratio may be used as the second liquid material. The coating film is subjected to heating for crystallization to form the second ferroelectric section 34. The ferroelectric layer 30 is formed in this manner.

(4) The second electrode 22 is formed on the second ferroelectric section 34. The second electrode 22 may be formed in the same manner as the first electrode 20. The ferroelectric capacitor C100 according to this embodiment is formed by these steps.

According to the method of manufacturing the ferroelectric capacitor C100 according to this embodiment, the ferroelectric layer 30 is formed by a plurality of steps using the liquid materials having different compositional ratios. In this embodiment, a liquid material having a Pb content lower than the Pb content of the second liquid material is used as the first liquid material. Therefore, the first ferroelectric section 32 formed by using the first liquid material is formed as a film in which a number of Pb vacancies with a negative effective charge of −1 occur in comparison with the second ferroelectric section 34 formed by using the second liquid material. Specifically, the ferroelectric layer 30 having a negative space charge concentration peak at a lower portion with respect to the film thickness (on the side of the first electrode 20) can be formed. Therefore, an internal bias field can be caused to occur in the ferroelectric layer 30 in the direction from the upper portion to the lower portion (or a direction from the second electrode 22 to the first electrode 20). As a result, the ferroelectric layer 30 suitable for nondestructive readout as described in the section of the background art can be provided.

Space charge concentration peaks are formed by forming the layers having defects at the upper and lower portions of the ferroelectric layer 30 in this embodiment. However, the present invention is not limited thereto. For example, two or more layers having defects at different percentages may be formed.

Modification

As another modification, a method of manufacturing the ferroelectric capacitor C110 shown in FIG. 3A is described below. This modification illustrates the case of forming the ferroelectric layer 30 having space charge concentration peaks of different polarities at the upper and lower portions in the direction of the thickness of the ferroelectric layer 30.

The first electrode 20 and the first and second ferroelectric sections 32 and 34 are formed by performing the steps (1), (2), and (3) of the above embodiment. The third ferroelectric section 36 is formed on the second ferroelectric section 34. As the third ferroelectric section 36, a film in which oxygen defects are caused to occur is formed. In more detail, a coating film (not shown) is formed on the second ferroelectric section 34 by using the second liquid material used in the above-described manufacturing method. The coating film is subjected to heating for crystallization. The third ferroelectric section 36 in which oxygen defects are intentionally generated can be formed by performing crystallization while reducing the oxygen partial pressure. The oxygen partial pressure is preferably set at 0.02 MPa or less. The ferroelectric layer 30 is formed in this manner. The ferroelectric capacitor C110 is thus formed. In this case, the chemical formula of PZT of the third ferroelectric section 36 is expressed by Pb²⁺(Zr⁴⁺Ti⁴⁺)(O²⁻□)₃, and the oxygen defect has an effective charge of +1.

The second electrode 22 is formed by performing the step (4) of the above embodiment.

According to the manufacturing method of this modification, the ferroelectric layer 30, in which the first ferroelectric section 32 in which lead vacancies are caused to occur is formed on the side of the first electrode 20 and the second ferroelectric section 34 in which oxygen vacancies are caused to occur is formed on the side of the second electrode 22, can be formed. Specifically, the ferroelectric layer 30 has a negative space charge concentration peak at the lower portion and a positive space charge concentration peak at the upper portion in the direction of the film thickness. As a result, an internal bias field occurs in the ferroelectric layer 30 in the direction from the upper portion (side of the second electrode 22) to the lower portion (side of the first electrode 20), whereby a ferroelectric capacitor including the ferroelectric layer 30 having hysteresis characteristics shifted to the left along the voltage axis, as indicated by the dashed line in FIG. 1, can be formed.

The case of using PZT as the ferroelectric layer 30 is described in this embodiment, but the ferroelectric layer 30 having space charge concentration peaks at the upper and lower portions with respect to the thickness of the ferroelectric layer 30 can be formed by using other ferroelectric materials.

In this embodiment, crystal defects such as lead defects or oxygen defects are created in the first ferroelectric section 32 or the third ferroelectric section 36 by appropriately adjusting the liquid material for the coating film or by appropriately adjusting the oxygen partial pressure during crystallization. However, crystal defects may be created by utilizing a method using a liquid material in which impurities are mixed. Specifically, crystal defects may be caused to occur by adding impurities to the first ferroelectric section 32 or the third ferroelectric section 36, thereby causing space charges to be generated in the first ferroelectric section 32 or the third ferroelectric section 36. As a method of adding impurities, a conventional doping method may be used. Table 1 shows examples of impurities which can be used.

TABLE 1

| | Impurities generating positive | Impurities generating negative |
|---|---|---|
| | effective charge | effective charge |
| PZT layer | Nb, Ta, La, Bi | Fe, Ni, Cr, Li, K, Na |
| ABT layer | W, Mo, La, Bi | Ti, Zr, K, Na |

In the case where the ferroelectric layer 30 is a PZT layer, a pentavalent element such as niobium is introduced as an impurity which causes a positive effective charge to occur. In this case, the chemical formula of PZT is expressed by Pb²⁺(Zr⁴⁺Ti⁴⁺X⁵⁺)0₃²⁻ (X═Nb), and niobium has an effective charge of +1. In the case of introducing a trivalent element such as lanthanum, the chemical formula of PZT is expressed by (Pb²⁺X³⁺)(Zr⁴⁺Ti⁴⁺)O₃²⁻ (X═La), and lanthanum has an effective charge of +1. As an impurity which causes a negative effective charge to occur, a trivalent element such as iron is introduced. In this case, the chemical formula of PZT is expressed by Pb²⁺(Zr⁴⁺Ti⁴⁺X³⁺)O₃²⁻ (X═Fe), and iron has an effective charge of −1. In the case of introducing a monovalent element such as sodium, the chemical formula of PZT is expressed by (Pb²⁺X³⁺)(Zr⁴⁺Ti⁴⁺)O₃²⁻ (X═Na), and sodium has an effective charge of −1.

In the case where the ferroelectric layer 30 is an SBT layer, a hexavalent element such as tungsten is introduced as an impurity which causes a positive effective charge to occur. In this case, the chemical formula of the SBT film is expressed by (Bi₂³⁺O₂²⁻)²⁺(Sr²⁺(Ta⁵⁺X⁴⁺)₂O₇²⁻ (X═W), and tungsten has an effective charge of +1. In the case of introducing a trivalent element such as lanthanum, the chemical formula of SBT is expressed by (Bi₂³⁺O₂²⁻)²⁺((Sr²⁺X³⁺)Ta₂⁵⁺O₇²⁻)²−, and lanthanum has an effective charge of +1. As an impurity which causes a negative effective charge to occur, a pentavalent element such as titanium is introduced. In this case, the chemical formula of the SBT film is expressed by (Bi₂³⁺O₂²⁻)²⁺(Sr²⁺(Ta⁵⁺X⁴⁺)₂O₇²⁻ (X═Ti), and titanium has an effective charge of −1. In the case of introducing a monovalent element such as sodium, the chemical formula of SBT is expressed by (Bi₂³⁺O₂²⁻)²⁺((Sr²⁺X¹⁺)Ta₂⁵⁺O₇²⁻)²⁻, and sodium has an effective charge of −1.

The amount of impurities to be added may be appropriately adjusted so that a desired internal bias field can be obtained. However, unintentional oxygen defects or lead defects may occur depending on the amount of impurities added in order to balance the entire charge of the ferroelectric layer 30. Therefore, it is preferable to adjust the amount of impurities to be added within the range in which the charge of impurities added is not neutralized.

It suffices that the second ferroelectric section 34 be a film in which the number of crystal defects is smaller than that of the first ferroelectric section 32 or the third ferroelectric section 36. The second ferroelectric section 34 is preferably formed at a composition close to the stoichiometric composition. The ferroelectric layer 30 is formed in this manner. The second electrode 22 is formed on the ferroelectric layer 30. The second electrode 22 may be formed by using the same material and formation method as those of the first electrode 20.

According to the manufacturing method of the embodiment of the present invention, space charges are caused to be generated in the first ferroelectric section 32 or the third ferroelectric section 36 by introducing impurities to cause crystal defects to occur. Therefore, the ferroelectric layer 30 having space charge concentration peaks at the lower portion (side of the first electrode 20) and the upper portion (side of the second electrode 22) of the ferroelectric layer 30, as shown in FIG. 3B, can be formed. As a result, the ferroelectric capacitor C110 including a ferroelectric film in which an internal bias field occurs can be formed.

What is claimed is:

1. A ferroelectric layer including space charges,
wherein the space charges show a concentration peak at least at one of an upper portion and a lower portion of the ferroelectric layer in a direction of the thickness of the ferroelectric layer.

2. The ferroelectric layer as defined in claim 1, wherein:
the space charges show a concentration peak at the upper portion and the lower portion of the ferroelectric layer; and
the polarities of the space charges at the upper and lower portions are different from each other.

3. A method of manufacturing a ferroelectric layer including space charges,
wherein the space charges are formed by causing a crystal defect to occur at least at one of an upper portion and a lower portion of the ferroelectric layer in a direction of the thickness of the ferroelectric layer.

4. The method of manufacturing a ferroelectric layer as defined in claim 3, wherein:
the space charges are formed by causing a crystal defect to occur at the upper portion and the lower portion of the ferroelectric layer; and
the polarities of the space charges at the upper and lower portions are different from each other.

5. A method of manufacturing a ferroelectric layer, comprising:
forming a first ferroelectric section including space charges generated by causing a crystal defect to occur; and
forming a second ferroelectric section over the first ferroelectric section.

6. The method of manufacturing a ferroelectric layer as defined in claim 5, further comprising:
forming a third ferroelectric section including space charges generated by causing a crystal defect to occur over the second ferroelectric section,
wherein the polarities of the space charges in the first ferroelectric section and the third ferroelectric section are different from each other.

7. The method of manufacturing a ferroelectric layer as defined in claim 3,
wherein the crystal defect is caused by the absence of part of substances in the stoichiometric composition of the ferroelectric layer.

8. The method of manufacturing a ferroelectric layer as defined in claim 3,
wherein the crystal defect is caused by crystallization heat treatment in which oxygen partial pressure is controlled.

9. The method of manufacturing a ferroelectric layer as defined in claim 3,
wherein the crystal defect is caused by introducing impurities.

10. The method of manufacturing a ferroelectric layer as defined in claim 5,
wherein the crystal defect is caused by the absence of part of substances in the stoichiometric composition of the ferroelectric layer.

11. The method of manufacturing a ferroelectric layer as defined in claim 5,
wherein the crystal defect is caused by crystallization heat treatment in which oxygen partial pressure is controlled.

12. The method of manufacturing a ferroelectric layer as defined in claim 5,
wherein the crystal defect is caused by introducing impurities.

13. A ferroelectric capacitor comprising the ferroelectric layer as defined in claim 1.

14. A ferroelectric capacitor comprising the ferroelectric layer as defined in claim 2.

15. A ferroelectric memory comprising the ferroelectric capacitor as defined in claim 13.

16. A ferroelectric memory comprising the ferroelectric capacitor as defined in claim 14.

17. The ferroelectric memory as defined in claim 15,
wherein the ferroelectric memory is operated by nondestructive readout.

18. The ferroelectric memory as defined in claim 16,
wherein the ferroelectric memory is operated by nondestructive readout.
